(19) United States
(12) Patent Application Publication
(10) Pub. No.: US 2006/0051921 A1
(43) Pub. Date: Mar. 9, 2006

(54) Methods of manufacturing semiconductor device gate structures by performing a surface treatment on a gate oxide layer

(75) Inventors: Sun-Pil Youn, Seoul (KR); Gil-Heyun Choi, Gyeonggi-do (KR); Chang-Won Lee, Gyeonggi-do (KR); Byung-Hak Lee, Gyeonggi-do (KR); Hee-Sook Park, Seoul (KR); Dong-Chan Lim, Seoul (KR); Jae-Hwa Park, Gyeonggi-do (KR); Woong-Hee Sohn, Gyeonggi-do (KR); Jong-Ryeol Yoo, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/215,504

(22) Filed: Aug. 30, 2005

(30) Foreign Application Priority Data
Sep. 7, 2004 (KR) 10-2004-0071140

(51) Int. Cl. H01L 21/336; H01L 21/31

(52) U.S. Cl. 438/257; 438/787

(57) ABSTRACT

In methods of manufacturing semiconductor devices, a preliminary gate oxide layer is formed on a substrate. A surface treatment process is performed on the preliminary gate oxide layer that reduces a diffusion of an oxidizing agent in the preliminary gate oxide layer to form a gate oxide layer on the substrate. A preliminary gate structure is formed on the gate oxide layer. The preliminary gate structure includes a first conductive layer pattern on the gate oxide layer and a second conductive layer pattern on the first conductive layer pattern. An oxidation process is performed on the preliminary gate structure using the oxidizing agent to form an oxide layer on a sidewall of the first conductive layer pattern and on the gate oxide layer, and to round at least one edge portion of the first conductive layer pattern.

### CROSS REFERENCE TO RELATED APPLICATION

This application claims the benefit under 35 USC § 119 of Korean Patent Application No. 2004-0071140, filed on Sep. 7, 2004, the disclosure of which is hereby incorporated herein by reference in its entirety as if set forth fully herein.

### FIELD OF THE INVENTION

The present invention relates to methods of manufacturing semiconductor devices. More particularly, the present invention relates to methods of manufacturing semiconductor devices including gate structures.

### BACKGROUND OF THE INVENTION

Semiconductor devices having a high integration degree and a rapid response speed may be highly desirable. Hence, technology of manufacturing semiconductor devices has been developed to improve integration degree, reliability and/or response speed of the semiconductor devices.

A semiconductor device having a high integration degree may utilize a multi-layered and miniaturized conductive wiring pattern. The conductive wiring or a gate electrode may include tungsten (W) instead of tungsten silicide (WSix).

A gate electrode for a Field Effect Transistor (FET) conventionally includes a structure having a polysilicon layer pattern and a tungsten silicide layer pattern on the polysilicon layer pattern. Alternatively, the gate electrode may include a structure having a polysilicon layer pattern and a tungsten layer pattern on the polysilicon layer pattern because tungsten has an electrical resistance smaller than that of tungsten silicide. Other material(s) also may be used.

To obtain the gate electrode including the tungsten layer pattern formed on the polysilicon layer pattern, various process conditions for manufacturing the gate electrode may be adjusted and further methods of manufacturing the gate electrode may be changed.

For example, when an etching process is performed for forming the gate electrode, damage to the gate electrode may be generated. The damage may be cured by performing a re-oxidation process on the gate electrode. When process conditions for curing the gate electrode including the tungsten silicide layer pattern are applied to the re-oxidation process for curing the gate electrode including the tungsten layer pattern, the tungsten layer pattern may be oxidized in the oxidation process, and thus the resistance of the gate electrode may increase and electrical failure of the gate electrode may be generated. Therefore, the process conditions of the re-oxidation process may be changed so as to reduce or prevent the oxidation of the tungsten layer pattern.

When an edge portion of the polysilicon layer pattern is sufficiently oxidized in the oxidation process, the polysilicon layer pattern may have a round edge portion, and thus a leakage current through the polysilicon layer pattern may be reduced. When the process conditions for reducing or preventing the oxidation of the tungsten layer pattern are applied, however, the edge portion of the polysilicon layer pattern may not be sufficiently oxidized in the re-oxidation process. Thus, the polysilicon layer pattern having a sharp edge portion may be obtained. An electric field may be concentrated at the sharp edge portion of the polysilicon layer pattern and a leakage current may be generated through the sharp edge portion of the polysilicon layer.

In addition, when process conditions for reducing or preventing oxidation of the tungsten pattern are applied, an oxidizing agent may be rapidly diffused into an inside of a gate oxide layer beneath the gate electrode. The gate oxide layer may be unevenly thickened and an edge portion of the gate oxide layer may be sharp. For example, the edge portion of the gate oxide layer may have a bird's beak shape. An electric field may be concentrated at the sharp edge portion of the gate oxide layer and a leakage current may be generated through the gate oxide layer. Therefore, reliability of a semiconductor device including the gate oxide layer may deteriorate.

U.S. patent application Publication No. 2002/0031870 discloses a gate structure including an oxide layer, a nitride layer formed on the oxide layer and a polysilicon layer formed on the nitride layer. Japanese Laid-Open Patent Publication No. 2002-222941 discloses a Metal Insulator Semiconductor (MIS) device including a gate structure that has a silicon nitride oxidized film and a polysilicon layer thereon. The polysilicon layer has a sharp edge portion.

### SUMMARY OF THE INVENTION

According to example embodiments of the present invention, a preliminary gate oxide layer is formed on a substrate. A surface treatment process is performed on the preliminary gate oxide layer that reduces and may even prevent diffusion of an oxidizing agent in the preliminary gate oxide layer to form a gate oxide layer on the substrate. A preliminary gate structure is formed on the gate oxide layer. In some embodiments, the preliminary gate structure includes a first conductive layer pattern on the gate oxide layer and a second conductive layer pattern on the first conductive layer pattern. An oxidation process is performed on the preliminary gate structure using the oxidizing agent to form an oxide layer on a sidewall of the first conductive layer pattern and on the gate oxide layer, and to round at least one edge portion of the first conductive layer pattern.

In some embodiments of the present invention, the surface treatment process may include a nitridation process such as a plasma nitridation process and/or a radical nitridation process. The nitridation may be performed under conditions that reduce diffusion of the oxidizing agent in the preliminary gate oxide layer but do not form a nitride layer on the preliminary gate oxide layer. The first conductive layer pattern may be formed using polysilicon doped with impurities, and the second conductive layer pattern may be formed using a tungsten-containing material.

According to other example embodiments of the present invention, a preliminary tunnel oxide layer is formed on a substrate. A surface treatment process for reducing or inhibiting diffusion of an oxidizing agent is performed on the preliminary tunnel oxide layer to form a tunnel oxide layer on the substrate. A preliminary gate structure is formed on the tunnel oxide layer. In some embodiments, the preliminary gate structure includes a floating gate pattern on the tunnel oxide layer, a dielectric layer pattern on the floating gate pattern and a control gate pattern on the dielectric layer pattern. An oxidation process is performed on the preliminary gate structure using the oxidizing agent to form an oxide layer on a sidewall of the floating gate pattern and on the tunnel oxide layer, and to round at least one edge portion of the floating gate pattern.

In some embodiments of the present invention, the surface of the oxide layer may be nitrided to reduce or suppress the thermal oxidation on the surface of the oxide layer beneath the gate structure. In the oxidation process of the preliminary oxide structure, the diffusion of the oxidant into the central portion of the oxide layer that is located under the gate structure may be reduced or prevented. Thus, the re-growth of the oxide layer may be reduced or suppressed in the oxidation process.

According to example embodiments of the present invention, damage that may be generated in an etching process to a gate structure may be cured, a first conductive layer pattern having a round edge portion may be obtained and/or an oxide layer having a uniform thickness may be obtained. Therefore, a leakage current from the gate structure may be reduced and reliability of a semiconductor device may be enhanced.

### BRIEF DESCRIPTION OF THE DRAWINGS

FIGS. 1 to 9 are cross-sectional views illustrating methods of manufacturing nonvolatile semiconductor devices in accordance with example embodiments of the present invention; and

FIGS. 10 to 13 are cross-sectional views illustrating methods of manufacturing field effect transistors in accordance with example embodiments of the present invention.

### DETAILED DESCRIPTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. Like numbers refer to like elements throughout. As used herein, the term “and/or” may include any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “beneath”, “below”, “lower”, “above”, “upper” and the like, may be used herein for ease of description to describe an element and/or a feature's relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” and/or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

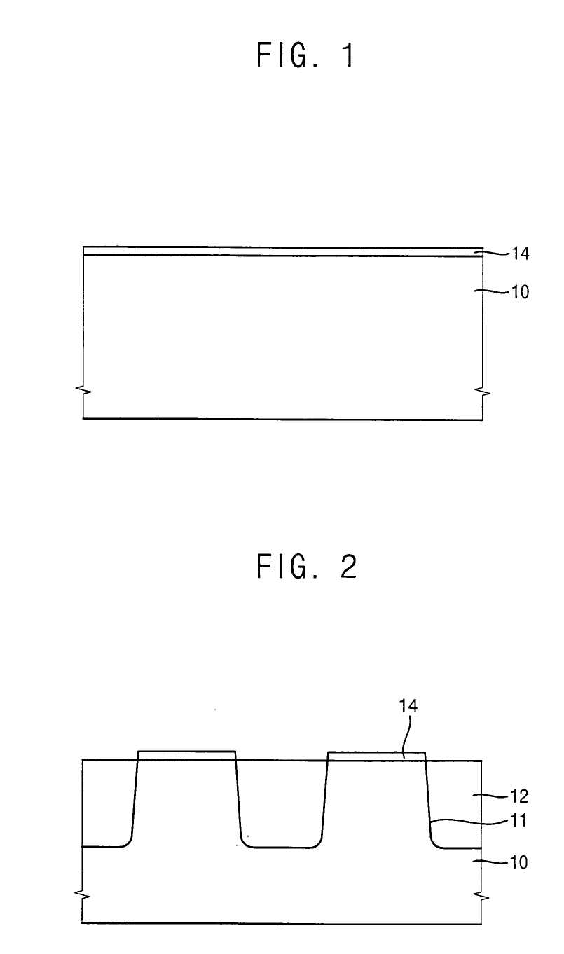

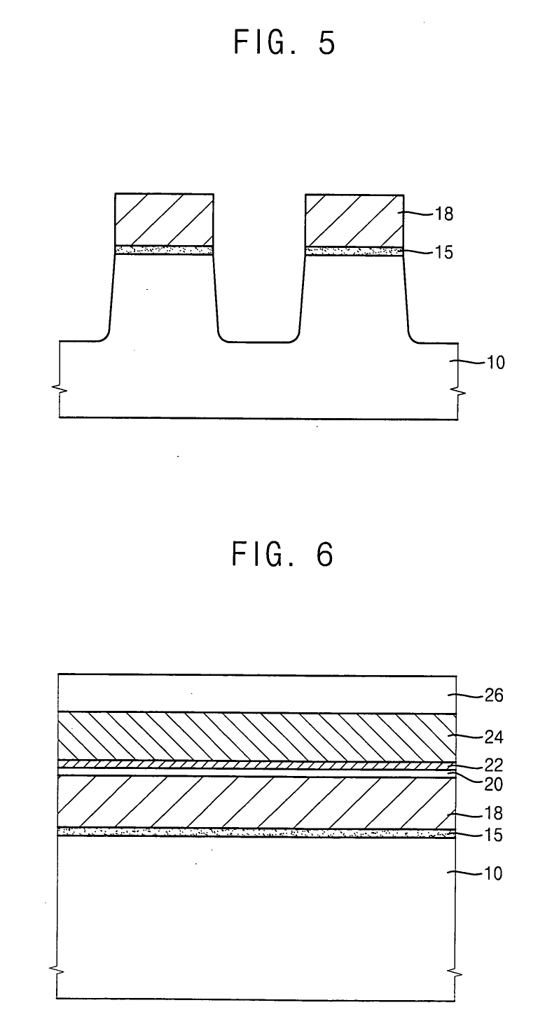

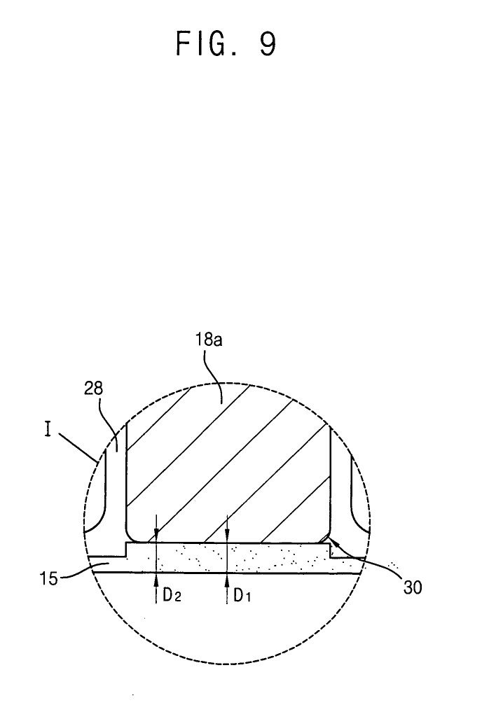

FIGS. 1 to 9 are cross-sectional views illustrating methods of manufacturing semiconductor devices such as nonvolatile semiconductor devices in accordance with example embodiments of the present invention. FIGS. 1, 3, 4 and 6 to 9 are cross-sectional views illustrating semiconductor devices such as nonvolatile semiconductor devices along a first direction parallel to an active region of the nonvolatile semiconductor device. FIGS. 2 and 5 are cross-sectional views illustrating semiconductor devices such as nonvolatile semiconductor devices along a second direction substantially perpendicular to the first direction. FIG. 9 is an enlarged cross-sectional view illustrating “I” in FIG. 8.

FIGS. 1 and 2 illustrate a step of forming a preliminary tunnel oxide layer 14 on a substrate 10. FIG. 1 is a cross-sectional view illustrating the preliminary tunnel oxide layer 14 formed on the substrate 10 along the first direction. FIG. 2 is a cross-sectional view illustrating the preliminary tunnel oxide layer 14 formed on the substrate 10 along the second direction.

Referring to FIGS. 1 and 2, a trench 11 is formed at an upper portion of the substrate 10. The substrate 10 may include a silicon wafer or a silicon-on-insulator (SOI) substrate. For example, the trench 11 is formed through a shallow trench isolation (STI) process. The substrate 10 may be partially etched using a dry etching process to form the trench 11. An insulation layer (not shown) is formed on the substrate 10 to fill up the trench 11. The insulation layer may be formed using an oxide such as tetraethyl orthosilicate (TEOS), undoped silicate glass (USG), spin on glass (SOG), high density plasma-chemical vapor deposition (HDP-CVD) oxide, etc. The insulation layer may be formed by a chemical vapor deposition (CVD) process, an HDP-CVD process, a plasma enhanced chemical vapor deposition process (PE-CVD), etc.

The insulation layer may be partially removed by a chemical mechanical polishing (CMP) process, an etch back process or a combination process of CMP and etch back until the substrate 10 is exposed. Thus, an isolation layer 12 is formed in the trench 11. When the isolation layer 12 is formed to fill up the trench 11, the active region and a field region are defined.

The preliminary tunnel oxide layer 14 is formed on the active region of the substrate 10. The preliminary tunnel oxide layer 14 may be formed by an oxidation process such as a thermal oxidation process. The preliminary tunnel oxide layer 14 may have a thickness varied in accordance with desired characteristics of the nonvolatile semiconductor device. For example, the preliminary tunnel oxide layer 14 may have a thickness of about 50 to about 200 Å when the nonvolatile semiconductor device has a design rule of below about 100 nm.

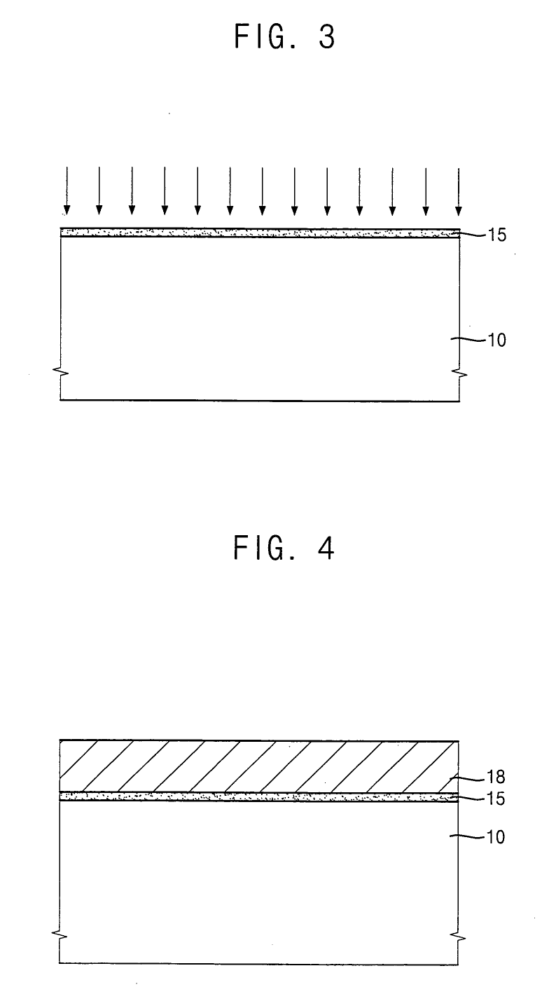

FIG. 3 is a cross-sectional view illustrating a step of forming a tunnel oxide layer 15 on the substrate 10 along the first direction.

Referring to FIG. 3, a surface treatment process that reduces or even inhibits (prevents) a diffusion of an oxidizing agent is performed on the preliminary tunnel oxide layer 14 such as indicated by arrows to thereby form the tunnel oxide layer 15 on the active region of the substrate 10. The surface treatment process may be performed by a nitridation process such as a plasma nitridation process, a radical nitridation process, etc. The surface treatment process may reduce or inhibit the diffusion of the oxidizing agent into a central portion of the preliminary tunnel oxide layer 14 in a subsequent oxidation process. The nitridation process transforms the preliminary tunnel oxide layer 14 into the tunnel oxide layer 15. Process conditions of the nitridation process may be adjusted in order not to form a nitride layer on the tunnel oxide layer 15. Thus, the nitridation process may be performed under conditions that reduce diffusion of the oxidizing agent in the preliminary gate oxide layer but do not form a nitride layer on the preliminary gate oxide layer. The tunnel oxide layer 15 may have a thickness substantially identical to that of the preliminary tunnel oxide layer 14. In contrast, when a nitride layer is formed on the tunnel oxide layer 15, the tunnel oxide layer 15 may be excessively thick. In addition, when a gate electrode is formed on the tunnel oxide layer 15 in a subsequent process, process conditions for forming a gate electrode may be changed because physical and chemical characteristics of the tunnel oxide layer 15 beneath the gate electrode may be varied.

When the surface treatment process is performed on the tunnel oxide layer 15, re-growth of the tunnel oxide layer 15 may be reduced or prevented in a subsequent oxidation process because nitrogen atoms in the surface of the tunnel oxide layer 15 may reduce or even prevent the diffusion of the oxidizing agent into the substrate 10 beneath a central portion of the tunnel oxide layer 15. In addition, when a silicon-containing layer may be formed on the tunnel oxide layer 15, the nitrogen atoms may reduce or prevent the diffusion of the oxidizing agent into the silicon-containing layer in the subsequent oxidation process.

In an example embodiment of the present invention, the surface treatment process may include using a plasma nitridation process. A surface of an object may be nitrided by nitrogen radicals in the plasma nitridation process. For example, in the plasma nitridation process, a nitrogen-containing gas such as nitrogen (N₂) gas, ammonia (NH₃) gas, etc. may be introduced into a chamber. An inactive (inert) gas may be introduced into the chamber. The nitrogen-containing gas may be excited to generate nitrogen plasma. The nitrogen-containing gas may be excited by applying a power of about 1000 to about 5000 W under a pressure of about 1 mTorr to about 10 Torr. The plasma nitridation process may be performed at a temperature of about 250 to about 600° C.

The plasma nitridation process may be performed for about 10 to 60 seconds. When the process time of the plasma nitridation process is less than about 10 seconds, the diffusion of the oxidizing agent into the substrate 10 beneath the tunnel oxide layer 15 may be not effectively prevented. When the process time of the plasma nitridation process is greater than about 60 seconds, an amount of the nitrogen atoms may be excessive in the tunnel oxide layer 15, and thus physical characteristics of the tunnel oxide layer 15 may be substantially changed and process conditions of successive processes may be not easily adjusted.

In one example embodiment of the present invention, the inactive gas may be introduced into the chamber in order to rapidly generate the nitrogen plasma. For example, the inactive gas may include argon (Ar). In another example embodiment of the present invention, the inactive gas may not be introduced into the chamber. When the inactive gas is not introduced into the chamber, a process time of the plasma nitridation process may be longer.

In another example embodiment of the present invention, the surface treatment process may be performed using a radical nitridation process. A surface of an object may be nitrided by nitrogen radicals in the radical nitridation process. For example, in the radical nitridation process, radicals may be generated by introducing a nitrogen-containing gas into a chamber and by applying a bias power to the nitrogen-containing gas. The nitrogen-containing gas may include nitrogen gas, ammonia gas, etc.

The tunnel oxide layer 15 formed through the surface treatment process may have an improved dielectric constant compared with a conventional tunnel oxide layer formed using silicon oxide. Thus, the preliminary tunnel oxide layer 14 may have a reduced thickness compared with the conventional tunnel oxide layer.

FIG. 4 is a cross-sectional view illustrating a step of forming a preliminary first conductive layer pattern 18 on the tunnel oxide layer 15 along the first direction. FIG. 5 is a cross-sectional view illustrating the step of forming the preliminary first conductive layer pattern 18 on the tunnel oxide layer 15 along the second direction.

Referring to FIGS. 4 and 5, a first conductive layer is formed on the tunnel oxide layer 15. The first conductive layer may be patterned in a successive process to form a floating gate of the nonvolatile semiconductor device. For example, the first conductive layer may be formed using polysilicon doped with N type impurities or P type impurities.

Although the P type impurities may be doped in the first conductive layer, the N type impurities may be advantageously doped into the first conductive layer because the floating gate may have improved characteristics when the floating gate is formed using polysilicon doped with N type impurities.

The first conductive layer is etched along the first direction to form the preliminary first conductive layer pattern 18 on the tunnel oxide layer 15. Here, the substrate 10 having the isolation layer 12 is exposed between the tunnel oxide layers 15.

FIG. 6 is a cross-sectional view illustrating steps of forming a dielectric layer 20, a barrier layer 22, a second conductive layer 24 and a hard mask layer 26 along the first direction.

Referring to FIG. 6, the dielectric layer 20 is formed on the preliminary first conductive layer pattern 18. The dielectric layer 20 may have an oxide/nitride/oxide structure that includes an oxide film, a nitride film and an oxide film sequentially formed on the preliminary first conductive layer pattern 18.

The barrier layer 22 is formed on the dielectric layer 20. The barrier layer 22 may be formed using a nitride such as tungsten nitride, etc. The barrier layer 22 may have a thickness of about 30 to about 100 Å. For example, when a tungsten-containing layer is formed on the barrier layer 22 in a successive process, the barrier layer 22 may prevent tungsten atoms from diffusing into the preliminary first conductive layer pattern 18.

The second conductive layer 24 is formed on the barrier layer 22. The second conductive layer 24 may be patterned in a successive process to form a control gate of the nonvolatile semiconductor device. The second conductive layer 24 may be formed using a metal. For example, the second conductive layer 24 may be formed using tungsten.

The hard mask layer 26 is formed on the second conductive layer 24. The hard mask layer 26 may be formed using a nitride such as silicon nitride.

In an example embodiment of the present invention, the barrier layer 22 may be formed on the preliminary first conductive layer pattern 18. The dielectric layer 20 may be formed on the barrier layer 22 and the second conductive layer 24 may be formed on the dielectric layer 20.

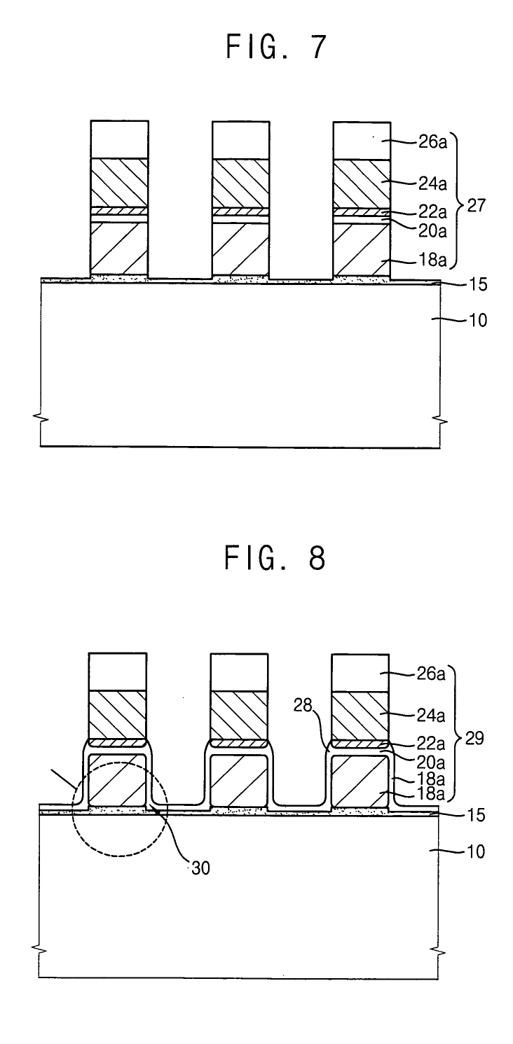

FIG. 7 is a cross-sectional view illustrating a step of forming a preliminary gate structure 27 along the first direction.

Referring to FIG. 7, the hard mask layer 26, the second conductive layer 24, the barrier layer 22, the dielectric layer 20 and the preliminary first conductive layer pattern 18 are etched along the second direction to form the preliminary gate structure 27. A photoresist pattern (not shown) may be formed on the hard mask layer 26. In one example embodiment of the present invention, the hard mask layer 26, the second conductive layer 24, the barrier layer 22, the dielectric layer 20 and the preliminary first conductive layer pattern 18 are successively etched using the photoresist pattern as an etching mask. In an etching process, the hard mask layer 26 is patterned to form a hard mask pattern 26a, the second conductive layer 24 is patterned to form a second conductive layer pattern 24a, the barrier layer 22 is patterned to form a barrier layer pattern 22a, the dielectric layer 20 is patterned to form a dielectric layer pattern 20a and the preliminary first conductive layer pattern 18 is patterned to form a first conductive layer pattern 18a. Thus, the preliminary gate structure 27 includes the first conductive layer pattern 18a, the dielectric layer pattern 20a, the barrier layer pattern 22a, the second conductive layer pattern 24a and the hard mask pattern 26a.

In another example embodiment of the present invention, the hard mask layer 26 is etched along the second direction using the photoresist pattern as an etching mask to form the hard mask pattern 26a. The second conductive layer 24, the barrier layer 22, the dielectric layer 20 and the preliminary first conductive layer pattern 18 are successively etched using the hard mask pattern 26a as an etching mask to form the preliminary gate structure 27.

Although an upper portion of the tunnel oxide layer 15 between the preliminary gate structures 27 may be partially etched in the etching process, the tunnel oxide layer 15 may still cover the active region of the substrate 10. When the tunnel oxide layer 15 between the preliminary gate structures 27 is completely removed from the substrate 10 in the etching process, a pitting of the active region of the substrate 10 may be generated in the etching process. Therefore, after the etching process, the tunnel oxide layer 15 may still cover the active region of the substrate 10 between the preliminary gate structures 27.

Each of the preliminary gate structures 27 has the first conductive layer pattern 18a formed on the tunnel oxide layer 15, the dielectric layer pattern 20a formed on the first conductive layer pattern 18a, the barrier layer pattern 22a formed on the dielectric layer 20a, the second conductive layer pattern 24a formed on the barrier layer 22a, and the hard mask pattern 26a formed on the second conductive layer pattern 24a the along the second direction. The first conductive layer patterns 18a of the preliminary gate structures 27 are isolated from one another along the first direction and the second direction.

FIG. 8 is a cross-sectional view illustrating a step of forming a gate structure 29 along the first direction. FIG. 9 is an enlarged cross-sectional view illustrating “I” in FIG. 8.

Referring to FIGS. 8 and 9, an oxidation process is performed on the preliminary gate structure 27 to form an oxide layer 28 and a gate structure 29. The oxidation process may cure damage to the preliminary gate structure 27 generated in the etching process. The oxidation process may be referred to as a re-oxidation process when the preliminary tunnel oxide layer 14 is formed using the oxidation process described with reference to FIGS. 1 and 2. The oxide layer 28 is formed on a sidewall of the first conductive layer pattern 18a and on the tunnel oxide layer 15 between the preliminary gate structures 27. Process conditions of the oxidation process may be adjusted to reduce or prevent an oxidation of a surface of the second conductive layer pattern 24a and to round at least one edge portion of the first conductive layer pattern 18a.

The oxide layer 28 may be formed by a wet oxidation process using an oxidizing agent. The oxidizing agent may include an oxygen-containing gas and a hydrogen gas. For example, the oxygen-containing gas may include oxygen (O₂) gas or water vapor (H₂O). A formation rate of the oxide layer 28 may be controlled by adjusting a partial pressure ratio of the oxygen-containing gas and the hydrogen gas. When the partial pressure of the oxygen-containing gas is reduced, the formation rate of the oxide layer 28 may be lower. When the partial pressure of the hydrogen gas is reduced, the surface of the second conductive layer pattern 24a may be oxidized. For example, the oxidizing agent may include oxygen gas and hydrogen gas with a partial pressure ratio between the oxygen gas and hydrogen gas by about 0.01:1 to about 10:1. Alternatively, the oxidizing agent may include water vapor and hydrogen gas with a partial pressure ratio between the water vapor and the hydrogen gas by about 0.2:1 to about 0.75:1.

The oxidation process for forming the oxide layer 28 may be performed at a temperature of about 800 to about 900° C. The oxidation process may be carried out using an oxidation apparatus having a batch type or a single type.

According to a conventional method of forming a gate structure, when a surface of a tunnel oxide layer is not nitrided, an oxidizing agent may be easily diffused into a central portion of the tunnel oxide layer beneath a floating gate in an oxidation process that is employed for curing damage to the gate structure generated by an etching process. The central portion of the tunnel oxide layer beneath the floating gate may be re-grown in the oxidation process so that the floating gate has a sharp edge. When power is applied to the floating gate, an electric field may be concentrated to the sharp edge of the floating gate and a leakage current may be generated. Therefore, an electrical failure of a nonvolatile semiconductor device having the floating gate may be generated and reliability of the nonvolatile semiconductor device may also deteriorate.

In accordance with example embodiments of the present invention, however, the surface of the tunnel oxide layer 15 may be nitrided by the surface treatment process. The nitrogen atoms in the surface of the tunnel oxide layer 15 may reduce or prevent the oxidizing agent from diffusing into the central portion of the tunnel oxide layer 15 beneath the first conductive layer pattern 18a in the oxidation process. The oxidizing agent may be concentrated in an edge portion of the first conductive layer pattern 18a. The edge portion of the first conductive layer pattern 18a may be oxidized and the first conductive layer pattern 18a has a round edge portion 30 as illustrated in FIG. 9. When electric power is applied to the nonvolatile semiconductor device, concentration of an electric field to the round edge portion 30 of the first conductive layer pattern 18a may be reduced or prevented and a leakage current may be reduced or prevented through the round edge portion 30 of the first conductive layer pattern 18a. Therefore, reliability and/or electrical characteristics of the nonvolatile semiconductor device may be enhanced.

In general, an oxidizing agent may be more easily diffused through an interface of a silicon oxide layer and a silicon layer because the interface of the silicon oxide layer and the silicon layer may have more defects than a bulk portion of the silicon oxide layer. According to a conventional method of forming the gate structure, when the surface of the tunnel oxide layer is not nitrided, the oxidizing agent may be easily diffused into the central portion of the tunnel oxide layer beneath the floating gate in the oxidation process. The tunnel oxide layer beneath the floating gate may be unevenly thickened and the edge portion of the tunnel oxide layer may be sharpened. The edge portion of the tunnel oxide layer may have a bird's beak shape. For example, when the oxidizing agent includes hydrogen gas, the edge portion of the tunnel oxide layer may be more sharpened. Therefore, the reliability and electrical characteristics of the conventional nonvolatile semiconductor device may deteriorate.

In accordance with example embodiments of the present invention, the tunnel oxide layer 15 having a uniform thickness may be provided because the diffusion of the oxidizing agent into the central portion of the tunnel oxide layer 15 beneath the first conductive layer pattern 18a employed as the floating gate may be reduced or prevented. For example, when the central portion of the tunnel oxide layer 15 has a first thickness D₁ and an edge portion of the tunnel oxide layer 15 has a second thickness D₂, the first thickness D₁ is substantially identical to the second thickness D₂ as illustrated in FIG. 9. Therefore, the nonvolatile semiconductor device having the tunnel oxide layer 15 and the first conductive layer pattern 18a may have enhanced electrical characteristics and the reliability of the nonvolatile semiconductor device may be enhanced.

After formation of the gate structure 29, source/drain regions and additional wiring may be formed to complete the semiconductor device.

FIGS. 10 to 13 are cross-sectional views illustrating methods of manufacturing field effect transistors in accordance with example embodiments of the present invention. These methods of manufacturing field effect transistors may be substantially identical to the methods of manufacturing nonvolatile semiconductor devices described with reference to FIGS. 1 to 9 except for the dielectric layer pattern.

FIG. 10 is a cross-sectional view illustrating a step of forming a gate oxide layer 104.

Referring to FIG. 10, an isolation layer 102 is formed at an upper portion of the substrate 100. For example, the isolation layer 102 is formed by an isolation process such as a shallow trench isolation (STI) process. An active region and a field region are defined by the formation of the isolation layer 102.

A preliminary gate oxide layer is formed on the active region of the substrate 100. For example, the preliminary gate oxide layer may be formed by an oxidation process such as a thermal oxidation process. The preliminary gate oxide layer may have a thickness of about 50 to about 200 Å.

A surface treatment process is performed on a surface of the preliminary gate oxide layer to form the gate oxide layer 104. The surface of the preliminary gate oxide layer may be treated by a nitridation process such as a plasma nitridation process or a radical nitridation process. The gate oxide layer 104 may have a nitrided surface. The surface treatment process can be substantially identical to the surface treatment process described with reference to FIG. 3. The surface treatment process transforms the preliminary gate oxide layer into the gate oxide layer 104.

When the surface treatment process is executed on the gate oxide layer 104, re-growth of the gate oxide layer 104 may be reduced or prevented in a subsequent oxidation process because nitrogen atoms in the surface of the gate oxide layer 104 may reduce or prevent diffusion of an oxidizing agent into the substrate 100 beneath a central portion of the gate oxide layer 104. In addition, when a silicon-containing layer may be formed on the gate oxide layer 104, the nitrogen atoms may reduce or prevent the diffusion of the oxidizing agent into the silicon-containing layer on the gate oxide layer 104 in the subsequent oxidation process.

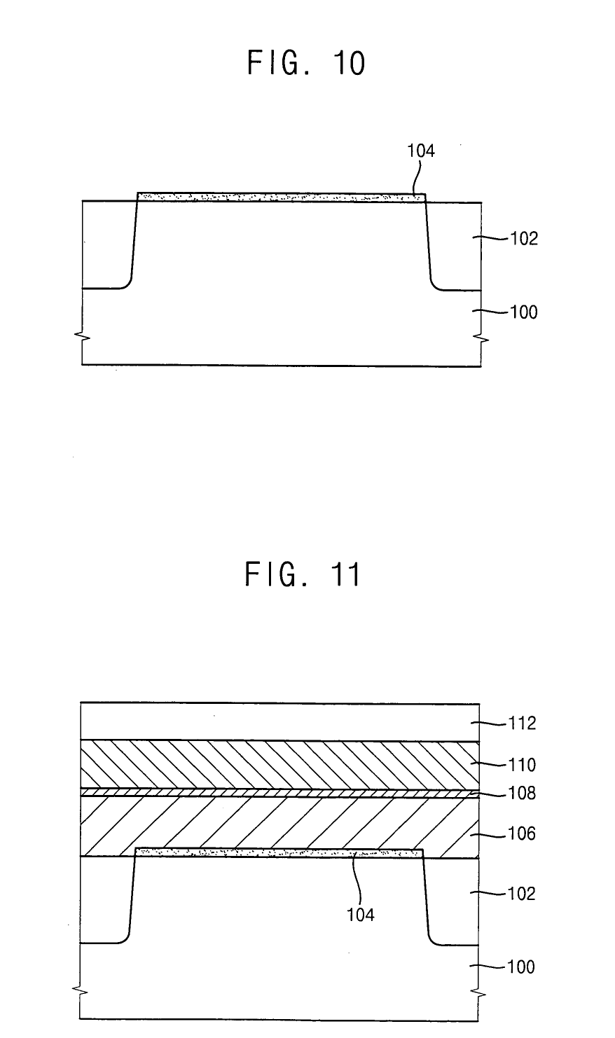

FIG. 11 is a cross-sectional view illustrating steps of forming a first conductive layer 106, a barrier layer 108, a second conductive layer 110 and a hard mask layer 112.

Referring to FIG. 11, the first conductive layer 106 is formed on the substrate 100 to cover the gate oxide layer 104. The first conductive layer 106 serves as a gate electrode. The first conductive layer 106 may be formed using polysilicon doped with N type or P type impurities. For example, when an N type transistor is desired, the first conductive layer 106 may be formed using polysilicon doped with the N type impurities. When a P type transistor is desired, the first conductive layer 106 may be formed using polysilicon doped with the P type impurities. In general, a unit cell of a dynamic random access memory (DRAM) device may include the N type transistor so that the first conductive layer 106 may be formed using polysilicon doped with the N type impurities.

The barrier layer 108 is formed on the first conductive layer 106. For example, the barrier layer 108 may be formed using a nitride such as tungsten nitride. The barrier layer 108 may have a thickness of about 30 to about 100 Å. When a tungsten-containing layer is formed on the barrier layer 108 in a successive process, the barrier layer 108 may reduce or prevent tungsten atoms from diffusing into the first conductive layer 106.

The second conductive layer 110 is formed on the barrier layer 108. The second conductive layer 110 serves as a control gate through a successive process. For example, the second conductive layer 110 may be formed using a metal such as tungsten.

The hard mask layer 112 is formed on the second conductive layer 110. For example, the hard mask layer 112 may be formed using a nitride such as silicon nitride.

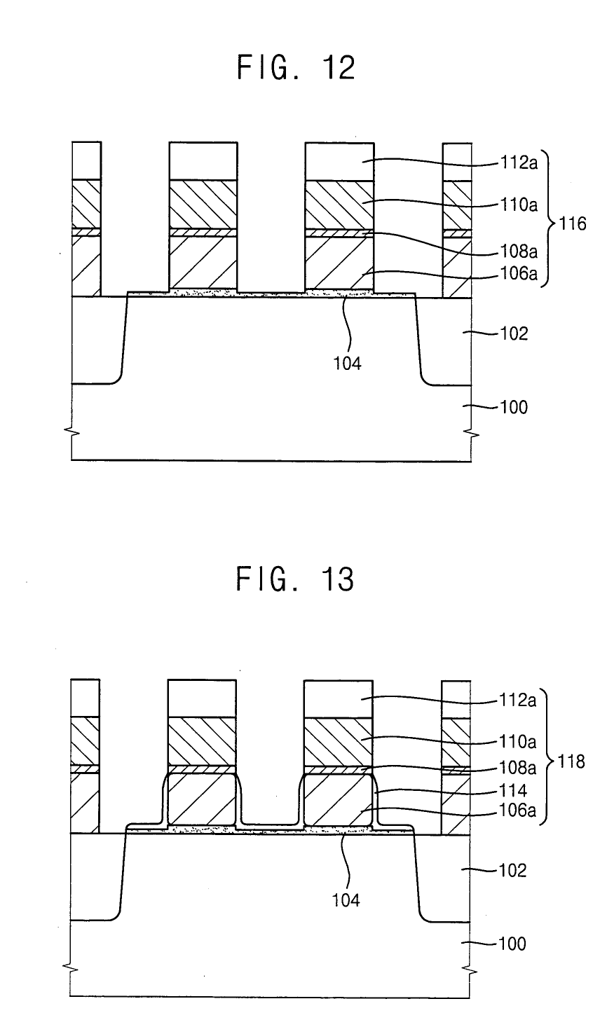

FIG. 12 is a cross-sectional view illustrating a step of forming a preliminary gate structure 116.

Referring to FIG. 12, the hard mask layer 112, the second conductive layer 110, the barrier layer 108 and the first conductive layer 106 are partially etched to form the preliminary gate structure 116. A photoresist pattern (not shown) may be formed on the hard mask layer 112. In one example embodiment of the present invention, the hard mask layer 112, the second conductive layer 110, the barrier layer 108 and the first conductive layer 106 are etched using the photoresist pattern as an etching mask to form the preliminary gate structure 116 on the gate oxide layer 104. In the etching process, the hard mask layer 112 is patterned to form a hard mask pattern 112a, the second conductive layer 110 is patterned to form a second conductive layer pattern 110a, the barrier layer 108 is patterned to form a barrier layer pattern 108a, and the preliminary first conductive layer pattern 106 is patterned to form a first conductive layer pattern 106a. Thus, the preliminary gate structure 116 includes the first conductive layer pattern 106a, the barrier layer pattern 108a, the second conductive layer pattern 110a and the hard mask pattern 112a. In another example embodiment of the present invention, the hard mask layer 112 is patterned using the photoresist pattern as an etching mask to form the hard mask pattern 112a. The second conductive layer 110, the barrier layer 108, the dielectric layer 20 and the preliminary first conductive layer pattern 106 are successively etched using the hard mask pattern 112a as an etching mask to form the preliminary gate structure 116 on the gate oxide layer 104.

FIG. 13 is a cross-sectional view illustrating a step of forming a gate structure 118.

Referring to FIG. 13, an oxidation process is performed on the preliminary gate structure 116 to form an oxide layer 114 and the gate structure 118. The oxidation process may at least partially cure damage to the preliminary gate structure 116 generated in the etching process. The oxidation process may be referred to as a re-oxidation process when the preliminary gate oxide layer 104 is formed by the oxidation process as described with reference to FIG. 10.

An oxide layer 114 is formed on a sidewall of the first conductive layer pattern 106a and on the gate oxide layer 104 between the gate structures 118. Processing conditions of the oxidation process may be adjusted to reduce or prevent an oxidation of a surface of the second conductive layer pattern 110a and to form a round edge portion of the first conductive layer pattern 106a.

The oxide layer 114 may be formed by a wet oxidation process using an oxidizing agent. The oxidizing agent may include an oxygen-containing gas and hydrogen gas. For example, the oxygen-containing gas may include oxygen (O₂) gas or water vapor (H₂O). The oxidation process can be substantially identical to the oxidation process described with reference to FIGS. 8 and 9.

In accordance with example embodiments of the present invention, the surface of the gate oxide layer 104 may be nitrided by the surface treatment process. The nitrogen atoms in the surface of the gate oxide layer 104 may reduce or prevent the oxidizing agent from diffusing into a central portion of the gate oxide layer 104 beneath the first conductive layer pattern 106a in the oxidation process. An edge portion of the first conductive layer pattern 106a may be oxidized and thus the first conductive layer pattern 106a has the round edge portion. When power is applied to the first conductive layer pattern 106a, concentration of an electric field to the round edge portion of the first conductive layer pattern 106a may be reduced or prevented and leakage current through the first conductive layer pattern 106a may be reduced or prevented. Therefore, the reliability and/or electrical characteristics of the transistor may be enhanced.

The gate oxide layer 104 having a uniform thickness may be provided because the diffusion of the oxidizing agent into the central portion of the gate oxide layer 104 beneath the first conductive layer pattern 106a may be reduced or prevented. A change of a threshold voltage of the transistor may be reduced or prevented due to the gate oxide layer 104 having the uniform thickness. Therefore, the transistor may have enhanced electrical characteristics and/or reliability.

The following Examples shall be regarded as merely illustrative and shall not be construed as limiting the invention.

### EXAMPLE 1

A gate structure of a nonvolatile semiconductor device was formed in accordance with an example embodiment of the present invention. A tunnel oxide layer was formed by a thermal oxidation process on an active region of a substrate on which an isolation layer was formed. The tunnel oxide layer had a thickness of about 61 Å. A surface of the tunnel oxide layer was nitrided by a plasma nitridation process. The plasma nitridation process was performed for about 40 seconds using nitrogen gas having a flow rate of about 500 standard cubic centimeters per minute (sccm) and argon gas having a flow rate of about 1,000 sccm. After a formation of a preliminary gate structure including a polysilicon layer pattern doped with N type impurities formed on the tunnel oxide layer, an ONO layer pattern was formed on the polysilicon layer pattern, a tungsten nitride layer pattern was formed on the ONO layer pattern, a tungsten layer pattern was formed on the tungsten nitride layer pattern and a silicon nitride layer pattern was formed on the tungsten layer pattern. Damage to the preliminary gate structure generated in an etching process was cured by an oxidation process at a temperature of about 850° C. An oxide layer having a thickness of about 10 Å was formed on a sidewall of the polysilicon layer pattern.

### COMPARATIVE EXAMPLE 1

A gate structure of a nonvolatile semiconductor device was formed using processes substantially identical to those of Example 1. However, a plasma nitridation process was not performed.

Evaluation of a Curvature of an Edge of a Floating Gate

Curvature radii of edge portions of the polysilicon layer patterns according to Example 1 and Comparative Example 1 were evaluated, respectively. The curvature radius of the edge portion of the polysilicon layer pattern according to Example 1 was about 2 nm. The curvature radius of the edge portion of the polysilicon layer pattern according to Comparative Example 1 was about 0 nm because the edge portion of the polysilicon layer pattern had a substantially right angle. Thus, the gate structure of the nonvolatile semiconductor device according to Example 1 includes a floating gate having a substantially round edge portion.

Evaluation of a Thickness of a Tunnel Oxide Layer

Thicknesses of tunnel oxide layers beneath the polysilicon layer patterns according to Example 1 and Comparative Example 1 were evaluated, respectively. Central portions of the tunnel oxide layers had first thicknesses, and edge portions of the tunnel oxide layers had second thicknesses. According to Example 1, both of the first thickness and the second thickness were about 61 Å. According to Comparative Example 1, the first thickness was about 64 Å and the second thickness was about 71 Å. A thickness of the tunnel oxide layer before the plasma nitridation process was about 61 Å. The thickness of the tunnel oxide layer according to Example 1 was not substantially changed after the oxidation process. Therefore, the plasma nitridation process prevented the tunnel oxide layer from being unevenly thickened in the oxidation process, in this Example 1.

Accordingly, methods of manufacturing semiconductor devices according to example embodiments of the present invention, as described herein, include forming a preliminary oxide layer on a substrate. A surface treatment is performed on the preliminary oxide layer that reduces diffusion of an oxidizing agent in the preliminary oxide layer, to thereby form a first oxide layer on the substrate. A preliminary gate structure is formed on the first oxide layer, wherein the preliminary gate structure includes a conductive layer pattern on the first oxide layer. An oxidization process is performed on the preliminary gate structure using the oxidizing agent to form a second oxide layer on a sidewall of the conductive layer pattern and to round at least one edge portion of the conductive layer pattern. In some embodiments, the surface treatment process comprises a nitridation process that is performed under conditions that reduce diffusion of the oxidizing agent in the preliminary oxide layer, but do not form a nitride layer on the preliminary oxide layer.

In accordance with example embodiments of the present invention, damage to a gate structure caused by an etching process may be at least partially cured. Additionally, a conductive layer pattern having a round edge portion may be obtained and a gate oxide layer having a relatively uniform thickness may be obtained. Therefore, a leakage current through the gate structure may be reduced or prevented and/or reliability and electrical characteristics of the nonvolatile semiconductor device may be enhanced.

The foregoing is illustrative of the present invention and is not to be construed as limiting thereof. Although a few example embodiments of this invention have been described, those skilled in the art will readily appreciate that many modifications are possible in the example embodiments without materially departing from the novel teachings and advantages of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of manufacturing a semiconductor device comprising:
forming a preliminary gate oxide layer on a substrate;
performing a surface treatment process on the preliminary gate oxide layer that reduces diffusion of an oxidizing agent in the preliminary gate oxide layer to form a gate oxide layer on the substrate;
forming a preliminary gate structure on the gate oxide layer, the preliminary gate structure including a first conductive layer pattern on the gate oxide layer and a second conductive layer pattern on the first conductive layer pattern; and
performing an oxidation process on the preliminary gate structure using the oxidizing agent to form an oxide layer on the gate oxide layer and on a sidewall of the first conductive layer pattern, and to round at least one edge portion of the first conductive layer pattern.

2. The method of claim 1, wherein the first conductive layer pattern is formed using polysilicon doped with impurities, and the second conductive layer pattern is formed using a tungsten-containing material.

3. The method of claim 1, wherein the surface treatment process comprises a nitridation process.

4. The method of claim 3, wherein the nitridation process is performed at a temperature of about 250 to about 600° C.

5. The method of claim 1, wherein the oxidation process comprises a wet oxidation process using the oxidizing agent that includes oxygen gas and hydrogen gas, or water vapor and hydrogen gas.

6. The method of claim 3, wherein the nitridation process is performed under conditions that reduce diffusion of the oxidizing agent in the preliminary gate oxide layer but do not form a nitride layer on the preliminary gate oxide layer.

7. The method of claim 1, wherein the oxidation process is performed at a temperature of about 800 to about 900° C.

8. The method of claim 1, further comprising forming a barrier layer pattern between the first conductive layer pattern and the second conductive layer pattern.

9. A method of manufacturing a semiconductor device comprising:
forming a preliminary tunnel oxide layer on a substrate;
performing a surface treatment process on the preliminary tunnel oxide layer that reduces diffusion of an oxidizing agent in the preliminary tunnel oxide layer to form a tunnel oxide layer on the substrate;
forming a preliminary gate structure on the tunnel oxide layer, the preliminary gate structure including a floating gate pattern on the tunnel oxide layer, a dielectric layer pattern on the floating gate pattern and a control gate pattern on the dielectric layer pattern; and
performing an oxidation process on the preliminary gate structure using the oxidizing agent to form an oxide layer on the tunnel oxide layer and on a sidewall of the floating gate pattern, and to round at least one edge portion of the floating gate pattern.

10. The method of claim 9, wherein the floating gate pattern is formed using polysilicon doped with impurities.

11. The method of claim 9, wherein the dielectric layer pattern has an oxide/nitride/oxide (ONO) structure.

12. The method of claim 9, wherein the control gate pattern is formed using a tungsten-containing material.

13. The method of claim 9, wherein the surface treatment process comprises a nitridation process.

14. The method of claim 9, wherein the surface treatment process is performed at a temperature of about 250 to about 600° C.

15. The method of claim 9, wherein the oxidation process comprises a wet oxidation process using the oxidizing agent that includes oxygen gas and hydrogen gas with a partial pressure ratio between the oxygen gas and the hydrogen gas of about 0.01:1 to about 10:1, or using the oxidizing agent that includes water vapor and hydrogen gas with a partial pressure ratio between the water vapor and the hydrogen gas of about 0.2:1 to about 0.75:1.

16. The method of claim 13, wherein the nitridation process is performed under conditions that reduce diffusion of the oxidizing agent in the preliminary tunnel oxide layer but do not form a nitride layer on the preliminary tunnel oxide layer.

17. The method of claim 9, wherein forming the preliminary gate structure comprises:
forming a preliminary first conductive layer pattern on the tunnel oxide layer;
forming a dielectric layer on the preliminary first conductive layer pattern;
forming a second conductive layer on the dielectric layer; and
patterning the preliminary first conductive layer pattern, the dielectric layer and, the second conductive layer to form the floating gate pattern, the dielectric layer pattern and the control gate pattern.

18. The method of claim 17, wherein forming the preliminary gate structure further comprises:
forming a barrier layer between the preliminary first conductive layer pattern and the second conductive layer; and
wherein the patterning comprises patterning the barrier layer to form a barrier layer pattern between the first conductive layer pattern and the second conductive layer pattern.

19. A method of manufacturing a semiconductor device comprising:
forming a preliminary oxide layer on a substrate;
performing a surface treatment process on the preliminary oxide layer that reduces diffusion of an oxidizing agent in the preliminary oxide layer to form a first oxide layer on the substrate;
forming a preliminary gate structure on the first oxide layer, the preliminary gate structure including a conductive layer pattern on the first oxide layer; and
performing an oxidation process on the preliminary gate structure using the oxidizing agent to form a second oxide layer on a sidewall of the conductive layer pattern, and to round at least one edge portion of the conductive layer pattern.

20. A method according to claim 19 wherein the surface treatment process comprises a nitridation process that is performed under conditions that reduce diffusion of the oxidizing agent in the preliminary oxide layer but do not form a nitride layer on the preliminary oxide layer.
